(19) United States
(12) Patent Application Publication
(10) Pub. No.: US 2026/0282261 A1
(43) Pub. Date: Sep. 17, 2026

(54) POWER ELECTRONICS COMPONENT, POWER CONVERTER ASSEMBLY, AND METHOD FOR ASSEMBLING MULTIPLE SUCH COMPONENTS

(71) Applicant: TRUMPF HÜTTINGER GMBH + CO. KG, Freiburg (DE)

(72) Inventors: Guido Dieter HODAPP, Emmendingen (DE); Thilo VETHAKE, Roosevelt, NJ (US)

(21) Appl. No.: 19/675,522

(22) Filed: May 13, 2026

Related U.S. Application Data
(63) Continuation of application No. PCT/EP2024/082603, filed on Nov. 15, 2024.

(30) Foreign Application Priority Data
Nov. 17, 2023 (DE) 10 2023 132 074.2

(51) Int. Cl. H05K 7/14; H02M 7/00; H05K 7/20

(52) U.S. Cl. CPC H05K 7/1432; H02M 7/003; H05K 7/2039; H05K 7/209

(57) ABSTRACT

A power electronics component, including a substrate, a semiconductor assembly arranged on the substrate, and at least two input power connections and at least two output power connections arranged on at least one side of the power electronics component. The power electronics component is configured such that the power electronics component can be joined with at least one other power electronics component of identical design in a stacking direction to form an assembly of power electronics components. The power electronics component is also configured such that the at least two input power connections can each be electrically connected to respective input power connections of the at least one other power electronics component via a first connection line, and the at least two output power connections can each be electrically connected to output power connections of the at least one other power electronics component via a second connection line.

### CROSS REFERENCE TO RELATED APPLICATIONS

This application is a continuation of International Application No. PCT/EP2024/082603 (WO 2025/104316A1), filed on Nov. 15, 2024, and claims benefit to German Patent Application No. DE 10 2023 132 074.2, filed on Nov. 17, 2023. The aforementioned applications are hereby incorporated by reference herein.

### FIELD

The invention relates to a power electronics component, a power converter assembly of a plurality of power electronics components, a method for assembling at least two power electronics components to form a power converter assembly, an electric power converter for a motor vehicle, and a power converter for coupling electrical networks or for an industrial process assembly.

### BACKGROUND

A power electronics component is often designed to operate in a power range ≥1 kW. For this purpose, such a component requires liquid-cooled operation. An electric power converter for a motor vehicle, for coupling electrical networks or for an industrial process assembly, e.g. plasma process assembly or heating assembly, having in particular a high-frequency amplifier assembly, may include a previously mentioned power electronics component and may in particular be designed to generate an HF output power, in particular for plasma excitation such as in plasma coating processes, preferably for the production of semiconductor structures.

There are particular challenges to cooling, particularly in the field of electric power converters for motor vehicles. Here, environmental conditions such as ambient temperature, humidity, pollution, but also vibration and load fluctuations are particularly high. For example, the ambient temperature has a strong effect on the temperature of the coolant. The requirements for efficiency and maximum dimensions are also particularly high.

There are also special challenges regarding cooling, particularly in the field of electrical network coupling. In hardly any other area are the requirements higher for efficiency and durability during continuous operation with a highly fluctuating power. One possible application is, for example, a charging and discharging device for large batteries, such as flow batteries. Since electrochemical efficiency during the charging and discharging of such batteries often presents a significant challenge, all the more effort is made to improve the efficiency and reliability of the power converters used for this purpose.

Efficiency can be improved if the inverters and/or power converters are kept within a defined temperature range and the required pumping power of coolant can be reduced.

There are also particular challenges for cooling, particularly in the field of electrical power conversion for special power-intensive and instability-prone industrial processes, such as plasma excitation, plasma coating processes, gas laser excitation, particle accelerators, melting of solids, heating and/or gasification of liquids by, for example, microwave energy or induction heating, or plasma torches. This can be a process for generating radiation, e.g. microwave radiation, X-rays or particle accelerators. A feature common to all of these processes is that they are designed to generate and accelerate charged atomic and subatomic particles in a gas and/or plasma environment or liquid. Another thing common to all of these processes is that they have a high power consumption, which is in the range of 1 kW or more, in particular 10 kW or more, preferably 100 kW or more. In this case, frequencies ≥20 kHz, preferably ≥200 kHz, and in particular ≥2 MHz, are generated for the aforementioned power range, either internally or for external applications. Many of these processes also have a very high requirement for the stability of the power supply because the processes are highly complex, such as semiconductor manufacturing using plasma processes and/or heating by electromagnetic fields. Typically, power is converted from a mains frequency, which is in the range of approximately 50 Hz to 60 Hz, to different frequencies, which can lie in the aforementioned range. Conversion to direct-current power, also called DC power, can also be provided. Even when converting to direct current power, the signal is often internally converted to a frequency in the aforementioned range for the power signal, which is then rectified again according to the requirements for voltage, current and power. For this conversion of electrical power into other frequencies, a large number of electronic components and assemblies are required, but in particular power semiconductor elements, such as transistors or diodes, in particular PIN diodes, for example for switching HF power between various paths, or a combination of transistor with diode designed for currents ≥10 A and voltages ≥400 V.

One particularly challenging area is plasma excitation processes, in particular plasma processing, such as coating (e.g. PVD, CVD) or etching. Such processes are used in the manufacturing of semiconductors such as microprocessor components and/or memory chips. Here, the requirements for reliability, durability and process repeatability are particularly high. At the same time, the required powers are also very high. Furthermore, the required output modulations, e.g. in modern electric power converters with an HF amplifier assembly or pulsed high voltage supply with pulse shaping, have steadily increased in recent times. One requirement for an HF amplifier assembly may be, for example, the ability to be pulsed at a plurality of different power levels, which is called multi-level pulsing (MLP). Another requirement for an HF amplifier assembly might be, for example, the ability to be frequency-adjustable and thus to react quickly to load changes, which is called auto frequency tuning (AFT). Another requirement may be, for example, the ability to provide a very high DC voltage, e.g. greater than or equal to 2 kV, in particular greater than or equal to 7 kV, which is pulsed, with pulse frequencies greater than or equal to 1 kHz, in particular greater than or equal to 10 kHz, particularly preferably greater than or equal to 200 kHz. With all these requirements, the requirement for power semiconductor elements, which are installed in the HF amplifier assembly and used to generate HF power, also increases.

The electronic components and assemblies generate waste heat during operation. The waste heat often arises over a very limited area of just a few mm², e.g. ≤8 mm². It is a particular challenge to dissipate this waste heat in order to protect the components and/or assemblies from destruction due to overheating. Often, very large and material-intensive heat sinks are provided for this purpose, the production of which is very expensive.

In the prior art, the heat quantity is dissipated by cooling using a cooling plate. When cooling with such a conventional cooling plate, the heat transfer from the electrical element, which may have a copper layer, to the cooling medium is achieved by applying a material, such as thermal paste, to the thermal interface, thereby dissipating the generated heat. Such a thermal interface material is disadvantageous. Firstly, it constitutes another heat transfer with thermal resistance, and secondly, it is subject to wear, which gradually degrades its effectiveness during operation. The surface area of the cooling plate is also increased, or the number and performance of the elements are reduced, in order to dissipate a larger amount of heat. Neither of the two options is sufficient. Since the installation space in the housing of such a power supply is limited, the cooling surface cannot be expanded indefinitely. Reducing the performance of individual elements is also not expedient. Overall, inadequate cooling of the electrical elements results in costs.

In particular, the requirement for these elements to convert power, which in certain conditions cannot be delivered to the load, into heat may also increase. These losses, which are converted into heat, can be ≥500 W in some applications, and in particular ≥1 kW. This heat must be dissipated from the power semiconductor elements, since otherwise they are destroyed by overheating.

In power electronics systems, there is also a need to be able to adapt the power for which the system is designed to a specific demand. One possibility for this is to design the power electronics system as a power converter assembly consisting of a plurality of power electronics components. The necessary electrical, thermal and fluidic connections result in high manufacturing effort and high material costs.

### SUMMARY

In an embodiment, the present disclosure provides a power electronics component, comprising a substrate, a semiconductor assembly arranged on the substrate, and at least two input power connections and at least two output power connections arranged on at least one side of the power electronics component. The power electronics component is configured such that the power electronics component can be joined with at least one other power electronics component of identical design in a stacking direction to form an assembly of power electronics components. The power electronics component is also configured such that the at least two input power connections of the power electronics component can each be electrically connected to respective functionally corresponding input power connections of the at least one other power electronics component via a first connection line assignable to the at least two input power connections, and the at least two output power connections of the power electronics component can each be electrically connected to respective functionally corresponding output power connections of the at least one other power electronics component via a second connection line assignable to the at least two output power connections.

### BRIEF DESCRIPTION OF THE DRAWINGS

Subject matter of the present disclosure will be described in even greater detail below based on the exemplary figures. All features described and/or illustrated herein can be used alone or combined in different combinations. The features and advantages of various embodiments will become apparent by reading the following detailed description with reference to the attached drawings, which illustrate the following:

FIG. 1 shows a power electronics component;

FIG. 2 shows connection surfaces of a transistor;

FIG. 3 shows a cross-section through a power electronics component;

FIG. 4 shows a cross-section through an embodiment of a power electronics component;

FIG. 5 shows a power converter assembly with two power electronics components;

FIG. 6 shows a circuit diagram of a three-pole inverter;

FIG. 7 shows a circuit diagram of a two-pole inverter;

FIG. 8 shows an industrial process assembly with an electric power converter;

FIG. 9 shows an electric power converter for coupling an electrical network; and

FIG. 10 shows an electric power converter for a motor vehicle.

### DETAILED DESCRIPTION

In an embodiment, the present disclosure provides a power electronics component and a power converter assembly of a plurality of such components which enable simplified interconnection of the components.

The power electronics component comprises a substrate, a semiconductor assembly arranged on the substrate, and at least two input power connections and at least two output power connections arranged on at least one side of the power electronics component. The power electronics component is designed in such a way that it can be joined with at least one other power electronics component of the same design, in particular identical design, in a stacking direction to form an assembly of power electronics components. Furthermore, the power electronics component is designed such that the input power connections of the power electronics component can each be electrically connected to the respective functionally corresponding input power connections of the at least one other power electronics component via a first connection line assignable to the input power connection, and the output power connections of the power electronics component can each be electrically connected to the respective functionally corresponding output power connections of the at least one other power electronics component via a second connection line assignable to the output power connection.

The power electronics component according to an embodiments of the present development can be assembled with other components of the same design to form an assembly. This assembly can also be called a stack assembly or a power converter assembly. Components of the same type are understood to be components which have dimensions and dimensioning designed in such a way that they can be assembled with the power electronics component in the stacking direction to form an assembly. The input power connections of the component are electrically connected to the input power connections of the at least one other component via first connection lines. This allows, for example, a parallel connection of the input power connections of the components. Similarly, the output power connections of the component are electrically connected to the output power connections of the at least one other component via second connection lines. This allows, for example, a parallel connection of the output power connections of the components. By connecting the input and output power connections of the modules in parallel, the respective powers of the individual components can, for example, contribute to a scalable overall power of the assembly. If the power requirement increases, further components can be added to the stack assembly, for example. Conversely, if power requirements decrease, components can be removed from the stack assembly. The individual power electronics components can be manufactured in large quantities and therefore cost-effectively. The interconnection of the components in the stack assembly by means of the first and second connection lines is simple and clear.

The development also concerns an assembly, also referred to as “stack assembly” or “power converter assembly”, of power electronics components, which comprises at least two power electronics components. The power electronics components each comprise a substrate, a semiconductor assembly arranged on the substrate, and at least two input power connections and at least one output power connection, which are arranged on at least one side of the power electronics component. The power electronics components are joined in a stacking direction to form the assembly. The assembly comprises at least two first connection lines assigned to the at least two input power connections of each power electronics component and at least one second connection line assigned to the at least one output power connection of each power electronics component. The corresponding input power connections of the power electronics components are electrically connected to each other by means of the at least two first connection lines and the corresponding output power connections of the power electronics components are electrically connected to each other by means of the at least one second connection line.

The power converter assembly according to an embodiment is assembled from at least two power electronics components. The input and output power connections of the components can be electrically connected to each other by means of the first and second connection lines. In this way, an assembly having an electrical power that is composed of the sum of the powers of the individual power electronics components can be provided. The power for which the assembly is designed is scalable. By adding or removing individual power electronics components, the power of the assembly can be changed, for example, and adapted to a changed demand.

Furthermore, the development relates to a method for assembling at least two power electronics components into a power converter assembly. The power electronics components each comprise a substrate, a semiconductor assembly arranged on the substrate, and at least two input power connections and at least one output power connection, which are arranged on at least one side of the power electronics component. The method comprises joining the at least two power electronics components in a stacking direction to form the assembly. Furthermore, the method comprises electrically connecting the corresponding input power connections of the power electronics components by means of at least two first connection lines and electrically connecting the corresponding output power connections of the power electronics components by means of at least one second connection line.

An embodiment also relates to an electric power converter for a motor vehicle, which has an assembly or power converter assembly as described above. Furthermore, the development concerns a power converter for coupling electrical networks which has an assembly as described above.

Advantageous embodiments and developments, which can be used individually or in combination with one another, are the subject matter of the following description.

In an aspect, the input power connections of the power electronics component are designed such that corresponding input power connections of the power electronics component and of the at least one other power electronics component can be connected in parallel by means of the first connection lines, and that corresponding output power connections of the power electronics component and of the at least one other power electronics component can be connected in parallel by means of the second connection lines.

In an aspect, the power electronics component comprises at least three output power connections, wherein the output power connections of the power electronics component can each be electrically connected to the respective functionally corresponding output power connections of the at least one other power electronics component via a second connection line assignable to the output power connection. This allows the power electronics component to be designed as a three-phase inverter.

In an aspect, the power electronics component is a power converter, in particular an inverter.

In an aspect of the development, the power electronics component is designed as a two-phase inverter, which has a first DC input power connection, a second DC input power connection, a first AC output power connection, and a second AC output power connection. Thus, a complete bridge circuit, also referred to as a full bridge circuit, can be arranged on a power electronics component. The cooling is so efficient that the entire full bridge circuit can be arranged on a power electronics component, and a plurality of the full bridge circuits can be connected in parallel in a stack.

In an aspect, the power electronics component comprises a first current path and a second current path, each having two power semiconductor elements connected in series, wherein the node between the two power semiconductor elements of the first current path is directly or indirectly electrically connected to the first AC output power connection of the power electronics component, and wherein the node between the two power semiconductor elements of the second current path is directly or indirectly electrically connected to the first AC output power connection of the power electronics component.

In an aspect of the development, the power electronics component is designed as a three-phase inverter, which has a first DC input power connection, a second DC input power connection, a first AC output power connection, a second AC output power connection and a third AC output power connection. The cooling is so efficient that such a three-phase inverter can be arranged entirely on a power electronics component, and a plurality of the three-phase inverters can be connected in parallel in a stack.

In an aspect, the power electronics component comprises a first current path, a second current path and a third current path, each having two power semiconductor elements connected in series, wherein the node between the two power semiconductor elements of the first current path is electrically connected directly or indirectly to the first AC output power connection of the power electronics component, wherein the node between the two power semiconductor elements of the second current path is electrically connected directly or indirectly to the second AC output power connection of the power electronics component, and wherein the node between the two power semiconductor elements of the third current path is electrically connected directly or indirectly to the third AC output power connection of the power electronics component.

In an aspect, the substrate of each power electronics component has a metallized portion on at least one side. Preferably, the substrate is direct bonded copper (DBC) or direct bonded aluminum (DBA). According to alternative preferred embodiments, the substrate can be an AMB (active metal brazed) substrate, an IMB (insulated metal substrate) substrate, or a thick-film substrate.

In an aspect, the semiconductor assembly comprises at least one bare die. Such a bare die can, for example, be applied or soldered directly onto the metallized portion.

It is advantageous if the semiconductor assembly comprises at least one control connection which is guided out of the power electronics component separately from the power connections, preferably by means of a wire connection. The control connection lines can therefore, for example, be guided out to the side of the component.

It is advantageous if the power electronics component comprises a heat sink having a cooling channel through which coolant can flow and which is arranged on the side of the substrate facing away from the semiconductor assembly.

In an aspect, the input power connections of one of the power electronics components are each electrically connected to the respective corresponding input power connections of the other power electronics components via the first connection line assigned to the input power connection, and the output power connections of one of the power electronics components are each electrically connected to the respective corresponding output power connections of the other power electronics components via the second connection line assigned to the output power connection. The electrical connection of corresponding input and output power connections of the components allows, for example, a parallel connection of the input and output power connections.

It is advantageous if corresponding input power connections of the power electronics components are connected in parallel by means of the first connection lines and corresponding output power connections of the power electronics components are connected in parallel by means of the second connection lines. The parallel connection of the input and output power connections of the various components allows, for example, a multiplication of the power of an individual component. This makes it possible to scale the power of the assembly assembled from individual components. For example, if more power is needed than before, other components can be added to the assembly. If, on the other hand, the power provided by the assembly is not fully utilized, individual components can be removed again.

It is therefore advantageous if other power electronics components can be subsequently attached to the assembly.

In an aspect, the arrangement of the input power connections and the output power connections on at least one side of the power electronics component is the same for all power electronics components. The at least largely matching arrangement of the power connections simplifies, for example, the attachment of connection lines and the interconnecting of the components. Furthermore, the clarity is improved, which also reduces the risk of incorrect interconnection.

It is advantageous if the power electronics components are power electronics components of the same design. For example, connecting identical components in parallel makes it possible to multiply the power.

In an aspect of the development, the first and second connection lines extend next to each other without crossing over each other along at least one side of the assembly. By avoiding crossovers, a particularly simple cable routing can be achieved, with which the risk of short circuits or arc faults is low.

In an aspect, the first and second connection lines run parallel to each other. The parallel connection of the connection lines enables a space-saving, safe and clear interconnection of the components. In particular, the risk of faulty interconnections, short circuits and arc faults is reduced.

In an aspect, the first and second connection lines extend across all power electronics components. In particular, the connection lines are designed, for example, as continuous connection lines that electrically connect all the components of the assembly to each other.

In an aspect, the first and second connection lines run in a straight line or a slightly curved line on at least one side of the assembly.

In an aspect, the first connection lines and the second connection lines run within a plane that is provided on one side of the assembly. In this exemplary embodiment, a plane is provided on one side of the assembly in which the first and second connection lines are arranged. This allows, for example, a compact, space-saving and clear interconnection of the input and output power connections of the components. For example, the connection lines can be easily accessible, which simplifies maintenance.

In an aspect of the development, the stacking direction has a dominant vector component which runs perpendicular, in particular, to the substrates of the power electronics components. The components can be arranged, for example, exactly on top of each other or obliquely offset from one another.

In an aspect, the first and second connection lines run in the stacking direction of the assembly. Preferably, the connection lines run parallel to the stacking direction along the assembly, and more preferably along the entire stack.

It is advantageous if the stacking direction runs perpendicular to the substrates of the power electronics components. In this embodiment, the components are arranged one above the other in a stacking direction perpendicular to the substrates. As a result, for example, a compact and mechanically stable arrangement can be obtained.

In an aspect, the first and second connection lines are designed as strip-like conductors. Strip-like conductors are suitable, for example, for high currents because they can provide a comparatively large conductor cross-section. Furthermore, they enable, for example, reliable electrical connections to the power connections.

In an aspect, the first and second connection lines are connected to the power connections of the power electronics components via one of the following: at least one welded connection, at least one soldered connection. This enables electrical connections with low contact resistance.

In an aspect, the power electronics components are arranged in such a way in the assembly that an end face of a first power electronics component bears against the end face of an adjacent power electronics component facing the first power electronics component. Such a compact and therefore space-saving arrangement of the components is made possible, for example, because the individual components are each equipped with heat sinks to dissipate the heat generated during operation.

In an aspect, each power electronics component comprises a heat sink having a cooling channel through which coolant can flow, a coolant supply and a coolant discharge, wherein in the assembly of the power electronics components the heat sinks of the power electronics components are connected to form a cooling circuit. In particular, it is advantageous to connect the heat sinks of the components fluidically in such a way that a cooling circuit is formed. In this way, for example, it is no longer necessary to supply each heat sink with coolant separately. Instead, the coolant can, for example, be supplied to the cooling circuit via a central supply and discharged again via a central coolant discharge.

In an aspect, the development comprises an electric power converter for an industrial process assembly, preferably a plasma process assembly or a heating assembly, having a power converter assembly as described above or below, in particular designed to generate an HF output power.

In an aspect, the power electronics component comprises: two power semiconductor elements, in particular transistors, each having a first and a second power connection and a control connection, wherein both power semiconductor elements, in particular transistors, are connected in series via one of their power connections. A direct-current voltage or DC voltage can be connected to the remaining power connections, and a control electronics unit is further provided which is connected to the control connections of the power semiconductor elements, in particular the two transistors, and the control electronics unit is designed to transfer the power semiconductor elements, in particular transistors, from a first conducting state into a second conducting state, the conductivities of the two states being different, so that they can generate AC power, in particular HF power.

In an aspect, the electric power converter has: a printed circuit board on which a power transformer is arranged, having a primary winding and a secondary winding, wherein the primary winding is connected to the at least one power connection of the power semiconductor elements, in particular transistors, wherein the primary winding and the secondary winding of the power transformer are each designed as planar conductor tracks which are arranged in different positions on the printed circuit board, and the printed circuit board has a thermal connection to a carrier unit.

Further advantageous configurations are described in more detail below with reference to a number of exemplary embodiments shown in the drawings, to which the development is not limited, however.

In the following description of preferred embodiments of the present development, identical reference numerals designate identical or comparable components.

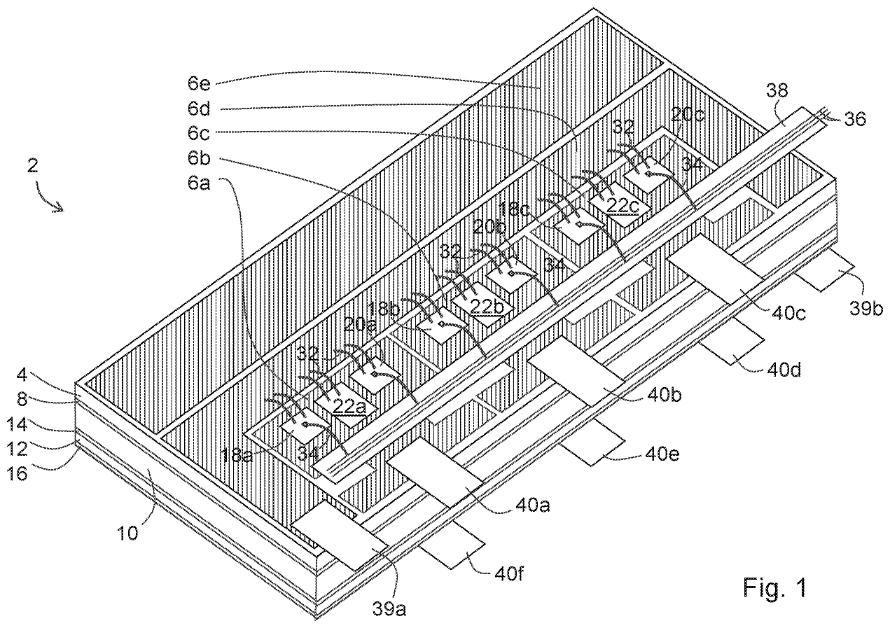

FIG. 1 shows a component 2, in particular for applications in the field of power electronics. The component 2 comprises a first substrate 4. The first substrate 4 has a first metallized portion 6 on the side of the component 2 facing the viewer and a second metallized portion 8 on the opposite second side. The first substrate 4 can preferably be a ceramic substrate with metallized portions applied to it. Preferably, the first substrate 4 is direct bonded copper (DBC) or direct bonded aluminum (DBA). Alternatively, the first substrate 4 could be an AMB (Active Metal Brazed) substrate.

A heat sink 10 is arranged on the side of the first substrate 4 facing away from the viewer in order to dissipate the heat generated by the semiconductor elements. The heat sink 10 is thermally and mechanically connected to the second metallized portion 8 of the first substrate 4. Preferably, the heat sink 10 is manufactured from a plurality of metal foils by means of a metal layer bonding process. To dissipate the heat, the heat sink 10 can, for example, have cooling channels through which coolant flows.

A second substrate 12 is arranged on the side of the heat sink 10 facing away from the first substrate 4. The second substrate 12 has a third metallized portion 14 on the side facing the heat sink 10 and a fourth metallized portion 16 on the side facing away from the heat sink 10. The second substrate 12 is thermally and mechanically connected to the heat sink 10 via the third metallized portion 14.

The first metallized portion 6 comprises a plurality of electrically separated metallized regions 6a to 6e, which are shown hatched in FIG. 1. Transistors 18a and 20a and a diode 22a are arranged in the metallized region 6a. Transistors 18a and 20a could, for example, be IGBTs or MOSFETs. The fourth metallized portion 16 facing away from the heat sink 10, just like the first metallized portion 6, can be subdivided into a plurality of metallized regions, on which semiconductor elements can be arranged.

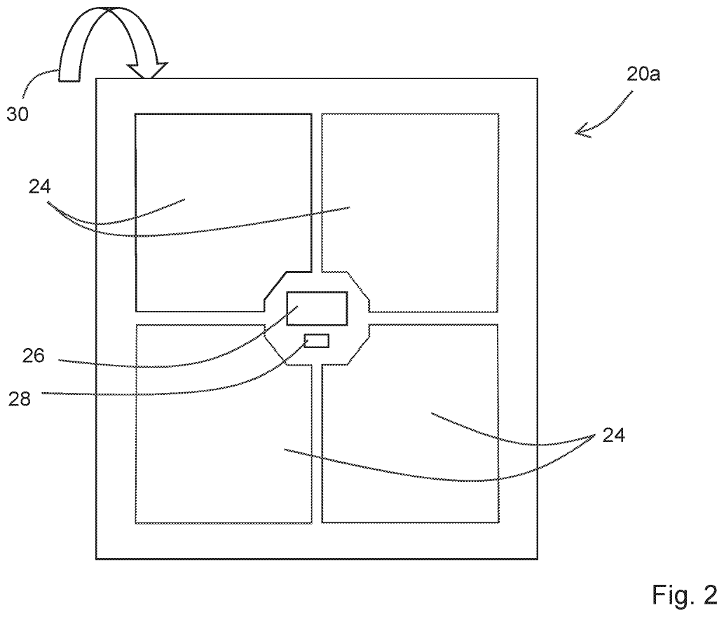

FIG. 2 shows an example of how the contact surfaces of a transistor, for example transistor 18a, can be designed. The transistor 18a shown by way of example in FIG. 2 has, on its first side, four emitter connection surfaces 24, a control connection surface 26 and a test connection surface 28 required for testing purposes. A collector connection surface 30 is provided on the rear side of transistor 18a.

As shown in FIG. 1, the transistors 18a and 20a are attached to the metallized region 6a such that an electrical contact is formed between the metallized region 6a and the collector connection surfaces of the transistors 18a and 20a. The emitter connection surfaces 24 of the transistors 18a and 20a are electrically connected to the metallized region 6d via first connecting wires 32. The diode 22a is also attached to the metallized region 6a. An electrical contact is formed between the metallized region 6a and a first power connection of the diode 22a. A second power connection of the diode 22a is electrically connected to the metallized region 6d via first connecting wires 32.

The control connections of the transistors can, for example, be guided out towards the side of component 2. In the embodiment shown in FIG. 1, the control connections of the transistors 18a and 20a are connected, for example, via second connecting wires 34 to control connection lines 36, which are guided out towards the side of the component 2 in or within an insulating region 38.

Two transistors 18b and 20b and a diode 22b are arranged in the metallized region 6b. The power connections of these semiconductor elements are electrically connected to the metallized region 6d via first connecting wires 32. The control connections of transistors 18b and 20b are electrically connected to the control connection lines 36 via second connecting wires 34.

Two transistors 18c and 20c and a diode 22c are arranged in the metallized region 6c. The power connections of these semiconductor elements are connected to the metallized region 6d via first connecting wires 32. The control connections of transistors 18c and 20c are electrically connected to the control connection lines 36 via second connecting wires 34.

A first input power connection 39a is arranged on the side of the component 2 and is electrically connected to the metallized region 6d. A second input power connection 39b is arranged on the side of the component 2 facing away from the viewer and is electrically connected to a metallized region of the fourth metallized portion 16. The first input power connection 39a and the second input power connection 39b protrude beyond the edge of the component 2.

Output power connections 40a, 40b, 40c are arranged on the side of the component 2. The output power connections 40a, 40b, 40c protrude beyond the edge of the component 2. The output power connection 40a is electrically connected to the metallized region 6a, the output power connection 40b is electrically connected to the metallized region 6b and the output power connection 40c is electrically connected to the metallized region 6c.

The fourth metallized portion 16 on the side of the component 2 facing away from the viewer, similarly to the first metallized portion 6, is also subdivided into different metallized regions. Other output power connections 40d, 40e, 40f are arranged on the side of the component 2 facing away from the viewer and protrude beyond the edge of the component 2. The output power connections 40d, 40e, 40f are each electrically connected to assigned metallized regions of the fourth metallized portion 16.

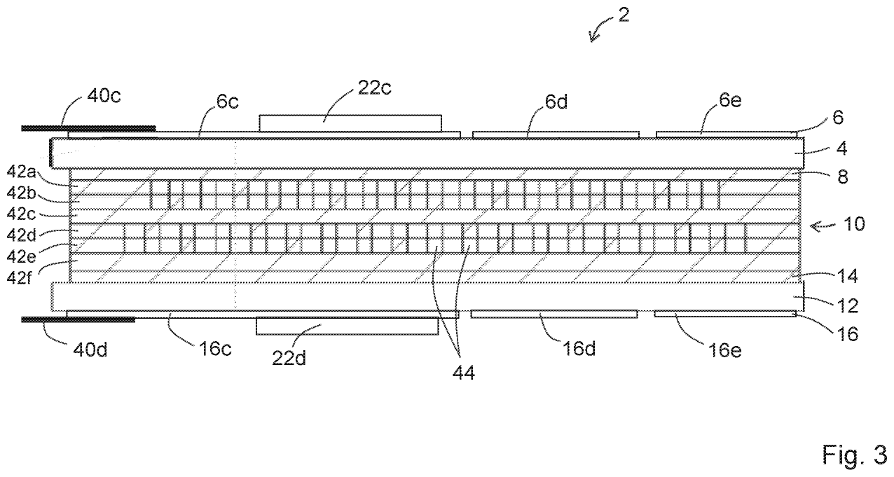

FIG. 3 shows a cross-section through the component 2. The metallized regions 6c, 6d, 6e of the first metallized portion 6 can be seen on the side of the first substrate 4 facing the viewer. The diode 22c can be seen in the metallized region 6c. The output power connection 40c is connected to the metallized region 6c.

On the side of the first substrate 4 facing away from the viewer, the second metallized portion 8 is thermally and mechanically connected to the heat sink 10. In the example shown in FIG. 3, the heat sink 10 is manufactured by means of a metal layer bonding process. In this process, individual metal foils 42a-42f, preferably copper foils, are structured at least partially by means of laser processing and/or punching and/or manufactured by means of electroplating processes and then joined together. The structuring or manufacturing is carried out in such a way that, after the layers are joined together, sealed cooling channels 44 are created through which a cooling medium can flow. A cooling channel structure allows the coolant to be guided in a manner directed to the areas of the heat sink 10 from which heat particularly needs to be dissipated. Preferably, the metal foils are connected to each other using a bonding process under high pressure and at high temperature. For this purpose, oxide layers can be formed on the surfaces of the copper layers, and are then welded together, the temperature being preferably chosen to be high enough that the oxide layers melt, but not the metal foils. This is how the metal foils are connected to form a monolithic heat sink. If the metal foils are made of copper, for example, this is also referred to as direct copper bonding, abbreviated DCB. The metal foils 42a-42f preferably have a thickness of 0.4 mm or less, in particular 0.25 mm or less.

There are different ways to produce the structure shown in FIG. 3. According to an embodiment, the first substrate 4, provided with metallized portions 6 and 8, and the heat sink 10 are each produced in separate steps. The heat sink 10 is then fixedly connected to the second metallized portion 8, for example by means of a bonding process, in particular by means of direct copper bonding. In this way, the second metallized portion 8 can be part of the heat sink 10, in particular the monolithic heat sink. According to a second, alternative manufacturing process, all layers, i.e., both the first substrate 4, the second metallized portion 8 and the metal foils 42a-42f, from which the heat sink 10 is formed, are connected to each other in a bonding process under high pressure and at high temperature, preferably by means of direct copper bonding and direct-bonded copper. Furthermore, preferably in the same step, the first metallized portion 6 is also applied to the upper side of the first substrate 4.

On the side of the heat sink 10 facing away from the viewer, the second substrate 12 is arranged with the third metallized portion 14 and the fourth metallized portion 16. The fourth metallized portion 16, similarly to the first metallized portion 6, can be subdivided into a plurality of metallized regions 16a to 16e. A diode 22d can be seen in the metallized region 16c. Furthermore, the output power connection 40d, which is electrically connected to the metallized region 16c, can be seen in FIG. 3.

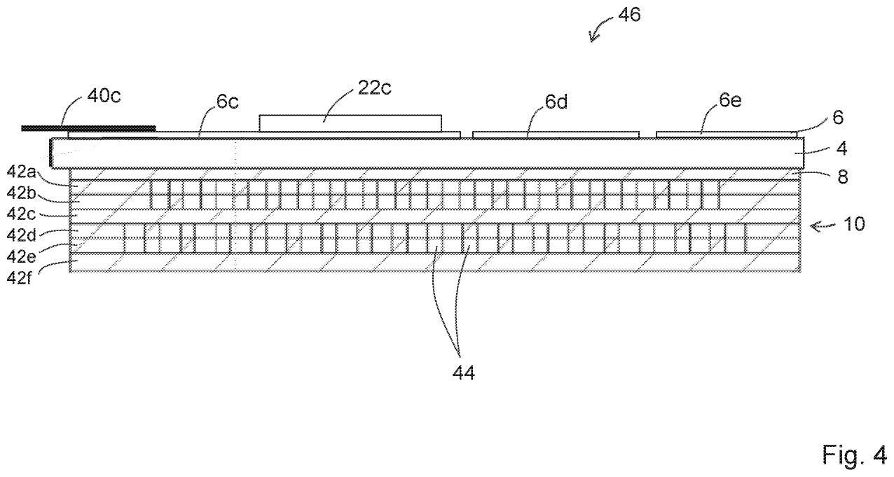

FIG. 4 shows an alternative embodiment of a component 46 which has only a substrate. This first substrate 4 with the metallized portions 6 and 8 is arranged on the side of the heat sink 10 facing the viewer. Another substrate is not arranged in this component 46 on the side of the heat sink 10 facing away from the viewer.

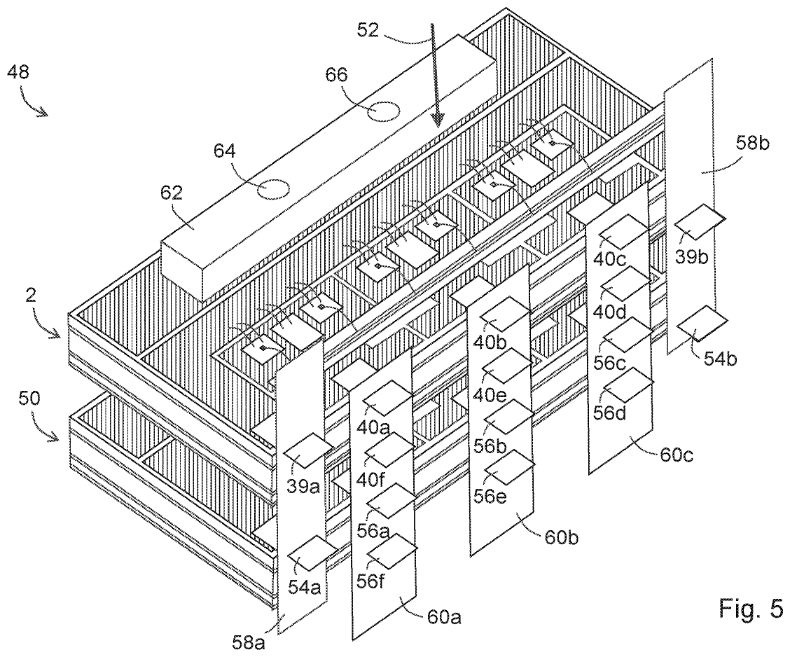

FIG. 5 shows an assembly 48, also referred to as: a “power converter assembly” 48, which consists of or comprises two or more stacked components. The assembly 48 shown in FIG. 5 comprises two components, namely the component 2 shown in FIG. 1 and another component 50 of the same design. The term “same design” here means that the dimensions of the other component 50 match the dimensions of component 2 at least to the extent that a stacked arrangement is provided. Furthermore, it is advantageous if the arrangement of the input power connections and the output power connections of the power electronics components to be stacked is at least substantially the same. Preferably, the two components 2 and 50 can be of identical design; however, such identical matching is not absolutely necessary.

The components 2 and 50 are stacked in a stacking direction 52. The stacking direction 52 in which the components 2, 50 are stacked runs either perpendicular to or in an inclined manner with respect to the planes defined by the substrates of the components 2, 50. Preferably, the dominant vector component of the stacking direction 52 runs perpendicular to the substrates of the power electronics components 2, 50.

The component 2 has the input power connections 39a, 39b and the output power connections 40a-40f. The further component 50 has the input power connections 54a, 54b and the output power connections 56a-56f.

The power converter assembly 48 of the components 2, 50 comprises a plurality of connection lines to interconnect the input power connections and the output power connections of the various components. In particular, first connection lines are provided, which are designed to electrically connect functionally corresponding input power connections of the components to each other. In addition, second connection lines are provided, which are designed to electrically connect functionally corresponding output power connections of the components to each other.

In particular, the power converter assembly 48 shown in FIG. 5 comprises a DC− input line 58a which electrically connects the input power connection 39a of the component 2 to the functionally corresponding input power connection 54a of the other component 50. Furthermore, the power converter assembly 48 comprises a DC+ input line 58b, which electrically connects the input power connection 39b of the component 2 to the functionally corresponding input power connection 54b of the other component 50. The DC− input line 58a and the DC+ input line 58b are first connection lines designed to electrically connect functionally corresponding input power connections of the components to each other. The DC− input line 58a and the DC+ input line 58b can, for example, be designed as strip-like connection lines that run without overlapping with each other. Preferably the first connection lines run parallel to each other, preferably in the stacking direction 52.

The power converter assembly 48 also comprises an AC-U output line 60a, which electrically connects the output power connections 40a, 40f, 56a, 56f to each other. The phase U of the AC voltage is tapped via the AC-U output line 60a. The AC-U output line 60a is connected to the first AC output power connection 61a.

The power converter assembly 48 also comprises an AC-V output line 60b which electrically connects the output power connections 40b, 40e, 56b, 56e to each other. The second phase V of the AC voltage can be tapped via the AC-V output line 60b. The AC-V output line 60b is connected to the second AC output power connection 61b.

Furthermore, the power converter assembly 48 comprises an AC-W output line 60c which electrically connects the output power connections 40c, 40d, 56c, 56d to each other. The third phase W of the AC voltage can be tapped via the AC-W output line 60c. The AC-W output line 60c is connected to the third AC output power connection 61c.

In the example shown in FIG. 5, the AC output lines 60a, 60b, 60c serve both to form electrical connections within a component and to interconnect functionally corresponding output power connections of various components to each other.

The AC-U output line 60a, the AC-V output line 60b and the AC-W output line 60c are therefore second connection lines designed to electrically connect functionally corresponding output power connections of the components to each other. The AC output lines 60a, 60b, 60c are preferably designed as strip-like connection lines which extend without crossing over each other along the power converter assembly 48. Preferably the AC output lines 60a, 60b, 60c are arranged parallel to each other and preferably run in the stacking direction 52.

In the embodiment shown in FIG. 5, all first connection lines and second connection lines are arranged within a plane on one side of the assembly 48 and run parallel to each other in this plane. This allows for a compact and clear interconnection of the 2, 50 components.

The first connection lines and the second connection lines are used to interconnect the functionally corresponding input power connections and output power connections in parallel to each other. By connecting a plurality of power electronics components in parallel, the partial power outputs of the individual units can be combined to form a complete unit with correspondingly greater power. The required power can therefore be provided in a scalable manner by connecting individual components in parallel. In particular, one or more other power electronics components can be subsequently added to an existing assembly, for example to adapt the power to new requirements. In this way, the power of the entire assembly can be scaled.

When joining the components to form a power converter assembly 48, the heat sinks of the individual components are preferably connected to form a common coolant circuit. For this purpose, the individual components 2, 50 can preferably have fluid ports, wherein fluidic connections are formed between the individual components when the components are stacked in order to realize a cooling circuit comprising all the heat sinks of the assembly 48. As shown in FIG. 5, the component 2 can be equipped with a coolant connection 62, which has a coolant supply 64 and a coolant discharge 66 for the coolant circuit.

In the example of FIG. 1, the component 2 can, for example, be designed as a three-pole inverter, with a plurality of these inverters being able to be joined to form an assembly 48 as shown in FIG. 5.

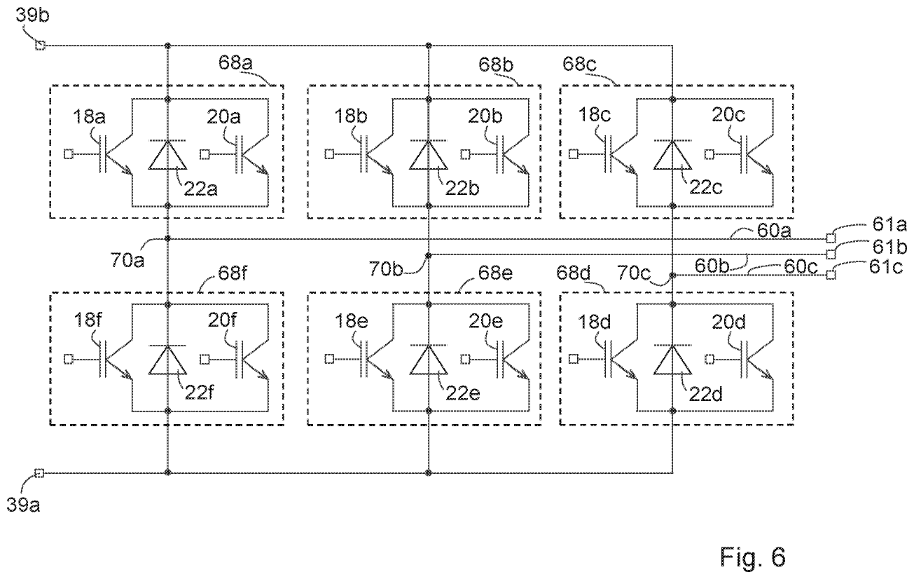

The circuit diagram of this component 2 is shown in FIG. 6. The circuit comprises the first input power connection 39a, which can be connected to the DC− input line 58a, and the second input power connection 39b, which can be connected to the DC+ input line 58b.

The circuit comprises six power switching units 68a to 68f. Each of the power switching units 68a to 68f comprises a transistor 18a-18f, a transistor 20a-20f and a parallel-connected diode 22a-22f. The control connections of the transistors are each electrically connected to at least one of the control connection lines 36.

The circuit has three current paths connected between the first input power connection 39a and the second input power connection 39b. The first current path comprises the series-connected power switching units 68a and 68f. The power switching unit 68a comprises the two transistors 18a and 20a and the diode 22a, which are attached to the upper side of the component 2 in the metallized region 6a. The control connections of the transistors 18a, 20a are connected to at least one of the control connection lines 36. The power switching unit 68f comprises the two transistors 18f and 20f as well as a parallel-connected diode 22f, which are arranged on a corresponding metallized region on the side of the component 2 facing away from the user. The control connections of transistors 18f, 20f are electrically connected to at least one of the control connection lines 36.

The power switching unit 68a and the power switching unit 68f are electrically connected to each other at a first node 70a. As can be seen in FIG. 5, the output power connections 40a and 40f of the component 2 are electrically connected to each other by the AC-U output line 60a. The first node 70a shown in FIG. 5 is thus created by the electrical connection of the output power connections 40a and 40f. The AC-U output line 60a is therefore connected to the first node 70a. The phase U of the AC output signal can be tapped at the first node 70a.

The second current path comprises the series-connected power switching units 68b and 68e. The two power switching units 68b and 68e are electrically connected to each other at a second node 70b. The second node 70b is created because the AC-V output line 60b electrically connects the output power connections 40b and 40e to each other. The AC-V output line 60b is therefore connected to the second node 70b. The phase V of the AC output signal can be tapped at the second node 70b.

The third current path comprises the series-connected power switching units 68c and 68f. The two power switching units 68c and 68f are electrically connected to each other at the third node 70c. The third node 70c is created because the AC-W output line 60c electrically connects the output power connections 40c and 40d to each other. The AC-W output line 60c is therefore connected to the third node 70c. The phase W of the AC output signal can be tapped at the third node 70c.

The inverter shown in FIG. 6 can, for example, be used in an electric vehicle. Alternatively, such an inverter can be used, for example, as a power converter for coupling electrical networks.

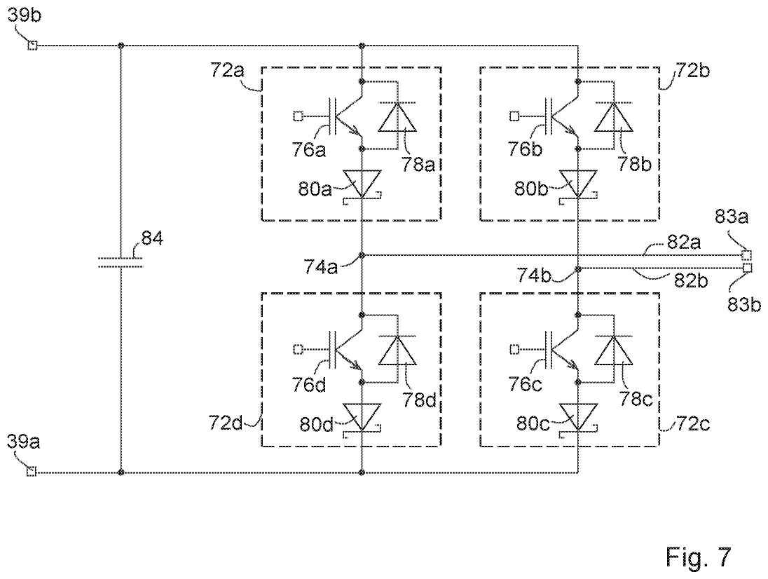

According to an alternative exemplary embodiment, the component can, for example, be designed as a two-pole inverter that converts a DC input voltage into an AC output voltage. A circuit diagram of such a two-pole inverter is shown in FIG. 7.

The circuit shown in FIG. 7 again comprises the first input power connection 39a, which can be connected to the DC− input line 58a, and the second input power connection 39b, which can be connected to the DC+ input line 58b.

In contrast to the embodiment shown in FIG. 6, the circuit of FIG. 7 has two current paths that are connected between the first input power connection 39a and the second input power connection 39b.

The first current path comprises a series connection of a power switching unit 72a and a power switching unit 72d, which are connected at a first node 74a to each other.

Similarly, the second current path comprises a series connection of a power switching unit 72b and a power switching unit 72c, which are connected to each other at a second node 74b. Each of the power switching units 72a-72d shown schematically in FIG. 7 comprises at least one transistor 76a-76d, at least one parallel-connected diode 78a-78d and at least one series diode 80a-80d, preferably a Schottky diode, connected in series therewith. An AC1 output line 82a is connected to the first node 74a and to a first AC output power connection 83a. An AC2 output line 82b is connected to the second node 74b and to a second AC output power connection 83b.

A capacitor 84 is also connected between the first input power connection 39a and the second input power connection 39b.

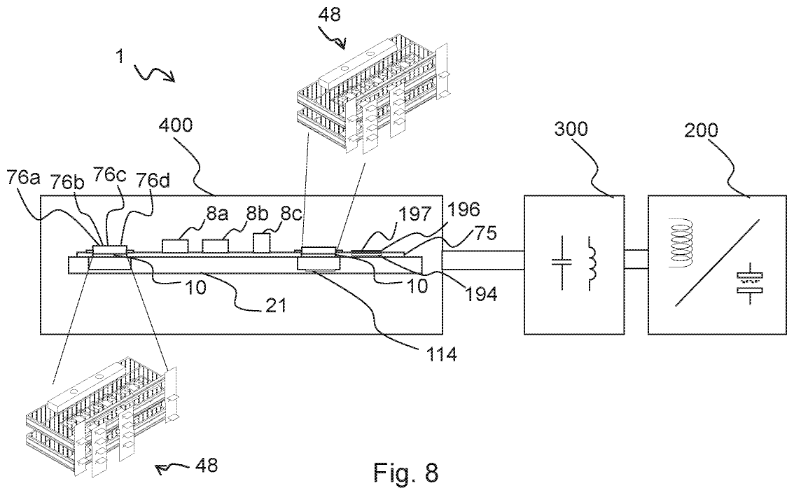

FIG. 8 shows an industrial process assembly 1 having an electric power converter 400 with an embodiment of a power converter assembly 48. The industrial process assembly is preferably a plasma process assembly or a heating assembly.

The industrial process assembly 1 has:
an electric power converter 400,
a load 200, preferably a plasma process or heating process, e.g., an induction or microwave heating process, the load 200 being electrically connected to the electric power converter 400 such that the electric power converter 400 can supply the load 200 with the required electrical power,
optionally an additional adaptation unit 300 which is connected between the power converter 400 and the load 200.

The power converter 400 has:
two of the power converter assemblies 48, as described above or below, for example in the description of FIGS. 1 to 7, with heat sinks 10,
a carrier unit (21),
a printed circuit board 75,
a unit to be cooled, in particular an electrical unit, preferably a semiconductor assembly, preferably having a power semiconductor element, in particular transistors 76a-76d,
other electronic components 8a, 8b, 8c,
the other electronic components 8a, 8b, 8c and the unit to be cooled being arranged on or against a printed circuit board 75 and connected to electrical contacts, and the unit to be cooled being fixedly connected, in particular integrally, to the heat sink 10.

Two power semiconductor elements, in particular transistors 76a-76d, are arranged as a unit 10 to be cooled against or on the printed circuit board 75, and each have a first and a second power connection and a control connection, and both transistors 76a-76d can be connected in series via one of their power connections. A direct-current voltage or DC voltage source can be connected to the remaining power connections via the input power connections 39a, 39b. A control electronics unit 114 can be connected to the control connections of the power semiconductor elements.

The power converter 400 is designed to provide an AC voltage, in particular an HF output power. Accordingly, it has a two-pole inverter as component 2, as shown, for example, in FIG. 7.

This can also be implemented as disclosed in WO2017/001599 A1.

A plurality of these inverters, as shown in FIG. 5, are joined to form an assembly 48.

A power transformer 197 is also arranged on the printed circuit board 75, having a primary winding 196 and a secondary winding 194. The primary winding 196 and the secondary winding 194 of the power transformer 197 are each designed as planar conductor tracks, which are arranged in different positions on the printed circuit board 75. The printed circuit board 75 has a thermal connection to the carrier unit 21, which is designed to cool the printed circuit board 75.

This can also be implemented as disclosed in WO2017/001602 A1.

The thermal connection to the carrier unit 21 can have a thermally conductive leveling layer, which is fixedly connected by its first surface to the first surface of the printed circuit board 75, and a connecting layer, which is fixedly connected by its first surface to the second surface of the thermally conductive leveling layer and by its second surface to the heat distributor. The thermal connection can be implemented, for example, as in the patent application with application number DE 10 2023 129 490.3, filed on Oct. 25, 2023.

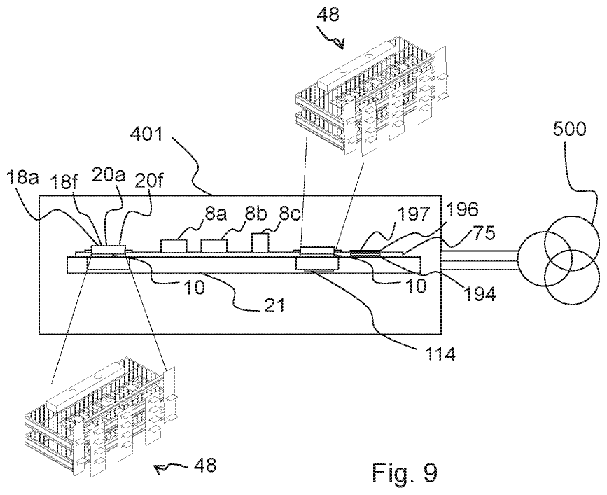

FIG. 9 shows an electric power converter 401 for coupling into an electrical network 500, which comprises a power converter assembly 48. The electric power converter 401 differs from the electric power converter 400 in that it has a three-phase connection for coupling into an electrical network 500. Accordingly, it has a three-pole inverter as component 2, as shown, for example, in FIG. 6. A plurality of these inverters, as shown in FIG. 5, are joined to form an assembly 48.

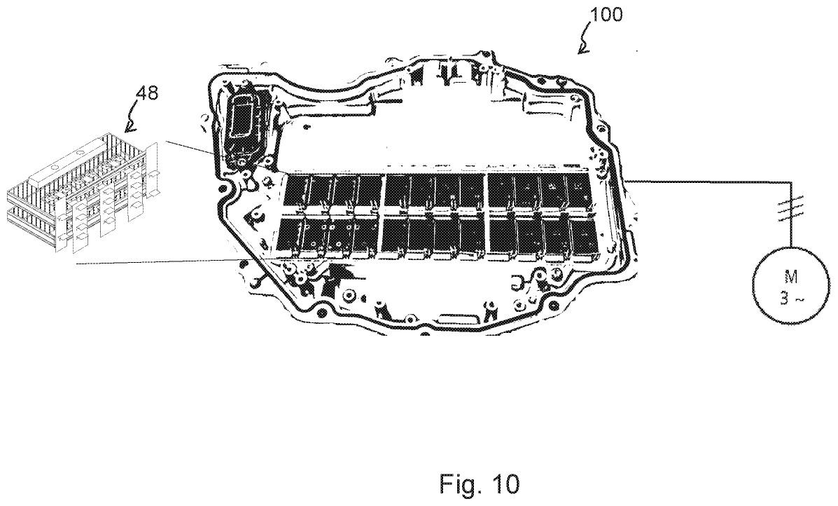

FIG. 10 shows an electric power converter 100 for an electric motor vehicle, which is suitable for supplying electrical power to an electric motor M 3~ connected to it or for taking this power from it and feeding it back, e.g. into a battery. This electric power converter 100 also has a power converter assembly 48. Electrically powered motor vehicles are usually operated using 3 phases. Accordingly, it has a three-pole inverter as component 2, as shown, for example, in FIG. 6. A plurality of these inverters, as shown in FIG. 5, are joined to form an assembly 48.

The features disclosed herein and illustrated in the drawings can be important both individually and in any combination for implementing the various configurations of the development.

While subject matter of the present disclosure has been illustrated and described in detail in the drawings and foregoing description, such illustration and description are to be considered illustrative or exemplary and not restrictive. Any statement made herein characterizing the invention is also to be considered illustrative or exemplary and not restrictive as the invention is defined by the claims. It will be understood that changes and modifications may be made, by those of ordinary skill in the art, within the scope of the following claims, which may include any combination of features from different embodiments described above.

The terms used in the claims should be construed to have the broadest reasonable interpretation consistent with the foregoing description. For example, the use of the article “a” or “the” in introducing an element should not be interpreted as being exclusive of a plurality of elements. Likewise, the recitation of “or” should be interpreted as being inclusive, such that the recitation of “A or B” is not exclusive of “A and B,” unless it is clear from the context or the foregoing description that only one of A and B is intended. Further, the recitation of “at least one of A, B and C” should be interpreted as one or more of a group of elements consisting of A, B and C, and should not be interpreted as requiring at least one of each of the listed elements A, B and C, regardless of whether A, B and C are related as categories or otherwise. Moreover, the recitation of “A, B and/or C” or “at least one of A, B or C” should be interpreted as including any singular entity from the listed elements, e.g., A, any subset from the listed elements, e.g., A and B, or the entire list of elements A, B and C.

1. A power electronics component, comprising:
a substrate;
a semiconductor assembly arranged on the substrate; and
at least two input power connections and at least two output power connections arranged on at least one side of the power electronics component,
wherein the power electronics component is configured such that:
the power electronics component can be joined with at least one other power electronics component of identical design in a stacking direction to form an assembly of power electronics components, and
the at least two input power connections of the power electronics component can each be electrically connected to respective functionally corresponding input power connections of the at least one other power electronics component via a first connection line assignable to the respective input power connection, and the at least two output power connections of the power electronics component can each be electrically connected to respective functionally corresponding output power connections of the at least one other power electronics component via a second connection line assignable to the respective output power connection.

2. The power electronics component according to claim 1, wherein the at least two input power connections of the power electronics component are configured such that the at least two input power connections of the power electronics component and corresponding input power connections of the at least one other power electronics component can be connected in parallel by the first connection lines, and wherein the at least two output power connections of the power electronics component are configured such that the at least two output power connections of the power electronics component and the output power connections of the at least one other power electronics component can be connected in parallel by the second connection lines.

3. The power electronics component according to claim 1, wherein the power electronics component comprises at least three output power connections, wherein the at least three output power connections of the power electronics component are each configured to be electrically connected to respective functionally corresponding output power connections of the at least one other power electronics component via the second connection line assignable to the respective output power connection.

4. The power electronics component according to claim 1, wherein the power electronics component is an inverter.

5. The power electronics component according to claim 1, wherein the power electronics component is configured as a two-phase inverter that includes:
a first direct current (DC) input power connection,
a second DC input power connection,
a first alternating current (AC) output power connection, and
a second AC output power connection.

6. The power electronics component according to claim 5, further comprising a first current path and a second current path, each of the first current path and the second current path having two power semiconductor elements connected in series, wherein a node between the two power semiconductor elements of the first current path is directly or indirectly electrically connected to the first AC output power connection of the power electronics component, and wherein a node between the two power semiconductor elements of the second current path is directly or indirectly electrically connected to the second AC output power connection of the power electronics component.

7. The power electronics component according to claim 1, wherein the power electronics component is configured as a three-phase inverter that includes:
a first DC input power connection,
a second DC input power connection,
a first AC output power connection,
a second AC output power connection, and
a third AC output power connection.

8. The power electronics component according to claim 7, further comprising a first current path, a second current path and a third current path, each having two power semiconductor elements connected in series, wherein a node between the two power semiconductor elements of the first current path is electrically connected directly or indirectly to the first AC output power connection of the power electronics component, wherein a node between the two power semiconductor elements of the second current path is electrically connected directly or indirectly to the second AC output power connection of the power electronics component, and wherein a node between the two power semiconductor elements of the third current path is electrically connected directly or indirectly to the third AC output power connection of the power electronics component.

9. The power electronics component according to claim 1, wherein the substrate of each power electronics component has a metallized portion on at least one side.

10. The power electronics component according to claim 1, wherein the semiconductor assembly comprises at least one bare die.

11. The power electronics component according to claim 1, wherein the semiconductor assembly comprises at least one control connection which is guided out of the power electronics component separately from the power connections.

12. The power electronics component according to claim 1, further comprising a heat sink having a cooling channel through which coolant is configured to flow and which is arranged on a side of the substrate facing away from the semiconductor assembly.

13. A power converter assembly, comprising:
at least two power electronics components,
wherein the power electronics components each have:
a substrate,
a semiconductor assembly arranged on the substrate, and
at least two input power connections and at least one output power connection, which are arranged on at least one side of the respective power electronics component,
wherein the power electronics components are joined in a stacking direction to form the power converter assembly,
wherein the power converter assembly comprises at least two first connection lines assigned to the at least two input power connections of each power electronics component and at least one second connection line assigned to the at least one output power connection of each power electronics component,
wherein the input power connections of the power electronics components are electrically connected to each other by the at least two first connection lines and wherein the output power connections of the power electronics components are electrically connected to each other by the at least one second connection line.

14. The power converter assembly according to claim 13, wherein the at least two input power connections of one of the at least two power electronics components are each electrically connected to respective corresponding input power connections of the other of the at least two power electronics components via the first connection line assigned to the respective input power connection and wherein the at least one output power connection of one of the at least two power electronics components are each electrically connected to a respective corresponding output power connection of the other of the at least two power electronics components via the second connection line assigned to the respective output power connection.

15. The power converter assembly according to claim 13, wherein the input power connections of the at least two power electronics components are connected in parallel by the first connection lines and wherein the output power connections of the at least two power electronics components are connected in parallel by the second connection lines.

16. The power converter assembly according to claim 13, wherein other power electronics components are configured to be subsequently attached to the power converter assembly.

17. The power converter assembly according to claim 13, wherein an arrangement of the input power connections of the at least two power electronics components and the output power connections on at least one side of the at least two power electronics components is identical for all power electronic assemblies.

18. The power converter assembly according to claim 13, wherein the at least two power electronics components are power electronics components of a same design.

19. The power converter assembly according to claim 13, wherein the first and second connection lines extend next to each other without crossing over each other along at least one side of the power converter assembly.

20. The power converter assembly according to claim 13, wherein the first and second connection lines run parallel to each other.

21. The power converter assembly according to claim 13, wherein the first and second connection lines extend over all of the at least two power electronics components.

22. The power converter assembly according to claim 13, wherein the first and second connection lines run in a straight line or a slightly curved line on at least one side of the power converter assembly.

23. The power converter assembly according to claim 13, wherein the first connection lines and the second connection lines run within a plane provided on one side of the power converter assembly.

24. The power converter assembly according to claim 13, wherein the stacking direction has a dominant vector component.

25. The power converter assembly according to claim 13, wherein the first and second connection lines run in the stacking direction of the power converter assembly.

26. The power converter assembly according to claim 13, wherein the stacking direction runs perpendicular to the substrates of the at least two power electronics components.

27. The power converter assembly according to claim 13, wherein the first and second connection lines are configured as strip-like conductors.

28. The power converter assembly according to claim 13, wherein the first and second connection lines are connected to the input and output power connections of the at least two power electronics components via one of the following: at least one welded connection, and/or at least one soldered connection.

29. The power converter assembly according to claim 13, wherein the at least two power electronics components are arranged in the power converter assembly such that an end face of a first power electronics component of the at least two power electronics components bears against an end face of an adjacent power electronics component of the at least two power electronics components facing the first power electronics component.

30. The power converter assembly according to claim 13, wherein each power electronics component comprises a heat sink having a cooling channel through which coolant is configured to flow, a coolant supply, and a coolant discharge, wherein in the power converter assembly of the at least two power electronics components the heat sinks are connected to a cooling circuit.

31. A method for assembling at least two power electronics components to form a power converter assembly, wherein the at least two power electronics components each include:
a substrate,
a semiconductor assembly arranged on the substrate,
at least two input power connections and at least one output power connection, which are arranged on at least one side of the respective power electronics component,
the method comprising:
joining the at least two power electronics components in a stacking direction to form the power converter assembly;
electrically connecting the input power connections of the at least two power electronics components by at least two first connection lines and electrically connecting the output power connections of the at least two power electronics components by at least one second connection line.

32. An electric power converter of a motor vehicle, comprising the power converter assembly according to claim 13.

33. An electric power converter configured to be coupled into an electrical network, comprising the power converter assembly according to claim 13.

34. An electric power converter configured for an industrial process assembly, comprising:
the power converter assembly according to claim 13, the power converter assembly being configured to generate a high-frequency (HF) output power.

35. The electric power converter according to claim 33, wherein the at least two power electronics components comprise:
two transistors each having a first and a second power connection and a control connection, wherein the two transistors are connected in series via one of their respective first and second power connections, wherein a DC voltage is connected to the remaining power connections of the respective first and second power connections, wherein a control electronics unit is further provided which is connected to the control connections of the two transistors, and wherein the control electronics unit is configured to transfer the two transistors from a first conducting state into a second conducting state, the conductivities of the first and second conducting states being different, so that they are configured generate HF power.

36. The electric power converter according to claim 33, comprising a printed circuit board on which a power transformer having a primary winding and a secondary winding is arranged, wherein the primary winding is connected to the at least one power connection of the two transistors, wherein the primary winding and the secondary winding of the power transformer are each configured as planar conductor tracks arranged in different positions on the printed circuit board, and wherein the printed circuit board has a thermal connection to a carrier.
